(19) United States
(12) Patent Application Publication
(10) Pub. No.: US 2025/0301588 A1
(43) Pub. Date: Sep. 25, 2025

(54) MIXED HEIGHT CONTACTS FOR STRATEGIC ENABLING OF HIGH-SPEED SYSTEMS THROUGH A SOCKET USING AN INTERCONNECT LAYER

(71) Applicant: Intel Corporation, Santa Clara, CA (US)

(72) Inventors: Saikat MONDAL, Chandler, AZ (US); Srikant NEKKANTY, Chandler, AZ (US); Zhichao ZHANG, Chandler, AZ (US)

(21) Appl. No.: 18/615,172

(22) Filed: Mar. 25, 2024

(51) Int. Cl. H05K 7/10; H01L 23/50; H01L 23/538; H01R 33/94

(52) U.S. Cl. CPC H05K 7/1023; H01L 23/50; H01L 23/5386; H01R 33/94

(57) ABSTRACT

A processor package module includes a socket having a first side and a second side, where the second side includes interconnect joints. The socket further includes a root complex and a non-root complex over the first side. An interconnect layer is on the first side of the socket and has one or more levels of routing traces. A first set of socket pins connects the root complex and non-root package to the interconnect layer, where the first set of socket pins terminate at the interconnect layer.

### BACKGROUND

Performance in computer systems is a primarily based on the performance of the processors or CPUs (Central Processing Unit) and the effective bandwidth of the inputs/outputs (I/O). CPUs may support multiple types of I/Os and memory connectivity. For DRAM, the connectivity type may be DDRx, while for I/O devices the connectivity type may be PCI Express (Peripheral Component Interconnect Express) and universal serial bus (USB). In recent years, clock speeds have been plateauing and additional performance has been extracted by adding more CPUs. This creates a tradeoff between IO and compute.

For example, sockets in semiconductor packages are used to mount and connect integrated circuits (ICs) or chips, such as CPUs or system-on-a-chip (SOC) to a printed circuit boards (PCBs) or other components. Some semiconductor packages require a mix of different speed signaling segments between the CPU and other components via the socket. High speed signaling segments, for instance may be used for memory, PCIe (peripheral component interconnect express), and Ethernet/SerDes (Serializer and Deserializer) applications. Usually, the highest speed segment (or high-speed input output (HSIO) components) is a driving factor for the need to achieve faster bandwidth between the CPU and other components. One solution to achieve these faster speeds is by reducing overall socket z-height of the socket. However, reduction in socket z-height requires a low profile power delivery capacitor solution, which can be costly and challenging with increasing power requirements, along with other mechanical challenges. Another approach for selective speed scaling is by enabling a top side connector on the CPU chip to which other components can directly connect to. However, this solution requires a heatsink cut-out on the CPU chip to accommodate the top side connector accompanied by subsequent top side testing.

### BRIEF DESCRIPTION OF THE DRAWINGS

FIG. 1A illustrates a simplified cross-sectional schematic diagram illustrating a state-of-the-art processor package module in accordance with example embodiments of the disclosure.

FIG. 1B illustrates an enlarged cross-sectional schematic diagram of a traditional socket pin.

FIGS. 2A-2D illustrate simplified cross-sectional schematic diagrams of a processor package module having mixed-height socket contacts in accordance with one or more embodiments of the disclosure.

FIG. 3A illustrates an enlarged cross-sectional schematic diagram of a two-level interconnect layer in accordance with the disclosed embodiments.

FIG. 3B illustrates an angled cross-sectional schematic diagram of a high-speed socket pin that is coupled to, and terminates at, a single-level interconnect layer rather than extending through a z-height of the socket.

FIG. 3C illustrates a top view of the interconnect layer and the high-speed socket pin.

FIG. 4 illustrates an angled cross-sectional schematic diagram of a mid-speed socket pin extending through a single-level interconnect layer.

FIG. 5 illustrates a graph showing improvement in impedance when mixed-height socket pins of the disclosed embodiments are used.

FIG. 6 illustrates a computing device in accordance with one implementation of the disclosure.

### DESCRIPTION OF THE EMBODIMENTS

Mixed height contacts for strategic enabling of high-speed systems through a socket using an interconnect layer are described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

One or more embodiments described herein are directed to structures and architectures for fabricating an interconnect layer having one or more levels of routing traces to achieve shorter interconnect routing between two ultra-high speed complexes or packages that are connected to the socket. High-speed socket pins having a shorter z-height than conventional socket pins are used to connect the two ultra-high speed complexes through the interconnect layer of the socket, enabling much wider and faster bandwidth between the two packages. Conventional longer z-height socket pins that extend through the socket may be used to connect the ultra-high speed package to a processor board for lower-speed connections, enabling the use of mixed height socket pins. Embodiments may include or pertain to high-speed I/O and system-on-chip (SoC) technologies. One or more embodiments may be implemented to realize high-speed I/O between packages in SoCs of future technology nodes.

There is increased need for advanced semiconductor packages to achieve higher bandwidth rates between root packages (e.g., CPUs) and non-root packages (e.g., memory).

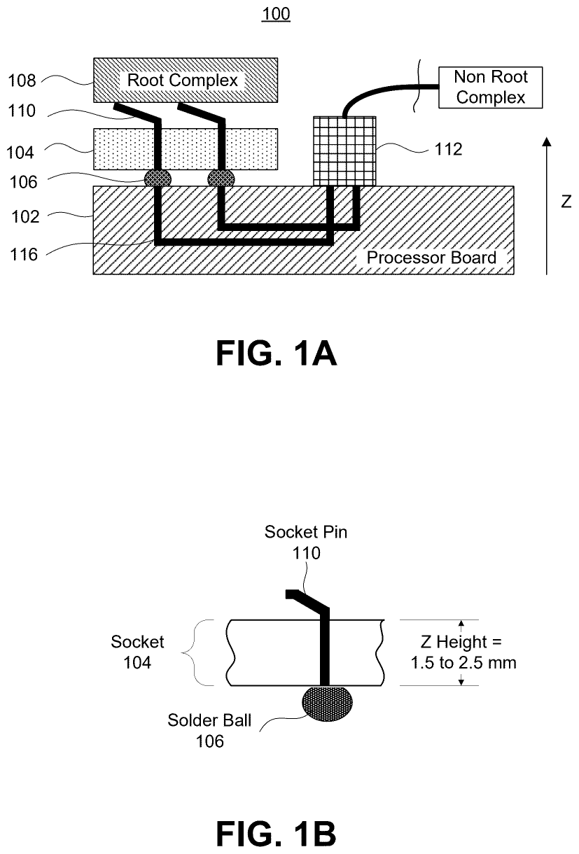

To provide context, FIG. 1A depicts a simplified cross-sectional schematic diagram illustrating a state-of-the-art processor package module 100 in accordance with example embodiments of the disclosure. The processor package module 100 includes a root complex package (e.g., a CPU) 108 and wire-to-board connector 112 mounted to one side of a socket 104. The wire-to-board connector 112 may be attached to another integrated circuit (I/C) device such as an add-in card or other type of non-root package, such as memory (not shown). The socket 104 is mounted to a processor board 102 with solder balls 106, while the root complex package 108 is mounted to the socket 104 with socket pins 110 that extend through the height of the socket 104. Signals from the root complex package 108 travel from the socket pins 110 through the socket 104 to board routing 116 in the processor board 102, and from the board routing 116 to the wire-to-board connector 112. The signals then propagate from the wire-to-board connector 112 to the non-root complex package for long channel reach, referring to the extended distance that the non-root complex package is located from the CPU or the root complex 108.

FIG. 1B illustrates an enlarged cross-sectional schematic diagram of a traditional socket pin. As shown, traditional socket pin 110 has a portion extending above the socket 104 and a portion that extends through the socket 104 and connects to solder ball 106. A typical socket 104 may have a z-height ranging from approximately 1.5 to 2.5 mm, which means the traditional socket pin 110 has a z-height greater than 1.5 to 2.5 mm.

In semiconductor packages, signals can be classified into three categories based on their speed or frequency range: low-speed signals, mid-speed signals, and high-speed signals. For high-speed signals within the processor package module 100, the length of connections is very important. In previous implementations reliant solely on onboard routing, both traditional socket pins 110 through the socket 104 and board routing 116 are responsible for conveying low-speed, mid-speed, and high-speed signals.

Since data rates double each node generation, the example implementation shown replaces some of board routing 116 with cable routing for long-reach applications since cable routing has less signal loss. However, the traditional socket pins 110 that extend through the height of the socket 104 and the remaining board routing 116 in the processor board 102 can be sources of channel discontinuity that impact the high-speed signals.

In accordance with one or more embodiments described herein, a process package architecture routes high-speed signals through the socket level, rather than the board level, and utilizes mixed-height socket pins to significantly improve impedance discontinuity. Such a scheme enables selective high-speed interconnects within the socket. In such an architecture, a root complex package and a non-root package are mounted to a side of the socket. An interconnect layer with one or more levels of routing traces is provided on the socket to connect the root complex package to the non-root package at the socket level. High-speed socket pins of the disclosed embodiments are used to connect the root complex package and the non-root package to the interconnect layer on the socket for high-speed signals. The high-speed socket pins terminate at the interconnect layer, rather than extend through the height of the socket. This results in the high-speed socket pins having a z-height that is less than the z-height of traditional socket pins to enable much wider bandwidth than the traditional socket pins. Conventional longer z-height socket pins that extend through the socket may be used to connect the root complex to a processor board for lower-speed connections, enabling the use of mixed-height socket pins and selective height scaling of specific socket pins.

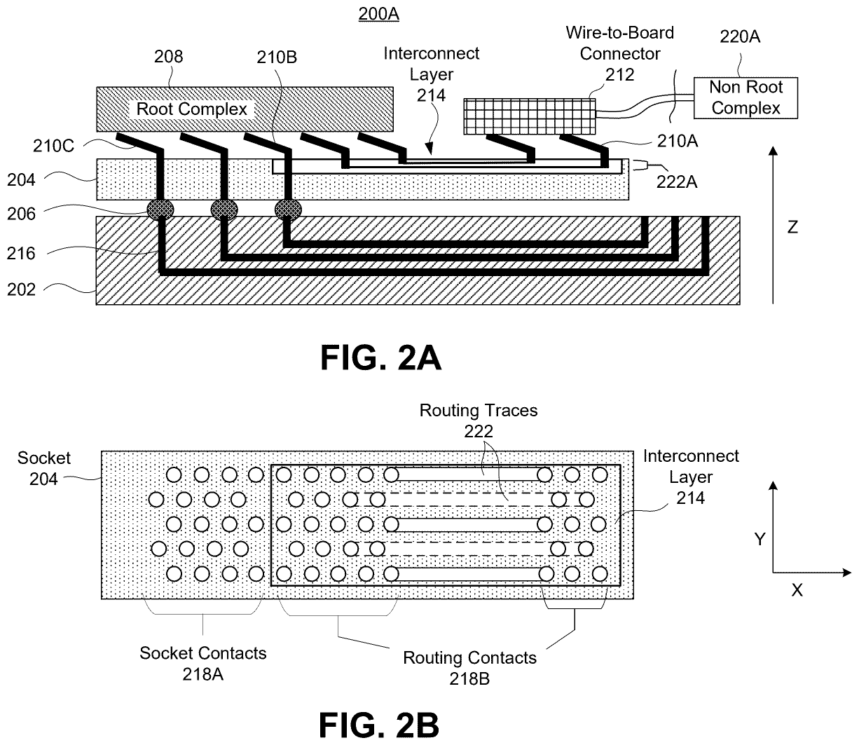

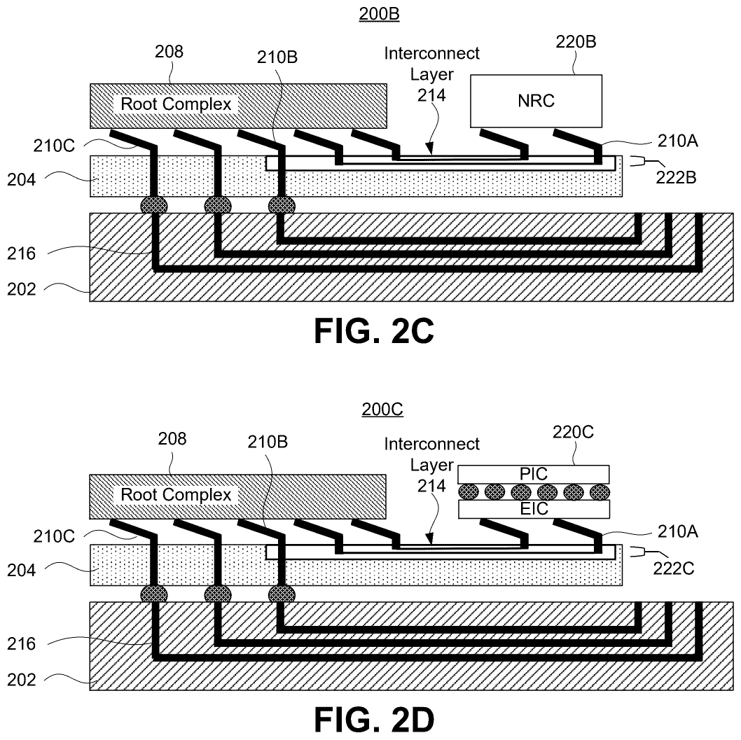

FIGS. 2A-2D illustrate simplified cross-sectional schematic diagrams of a processor package module having mixed-height socket contacts in accordance with one or more embodiments of the disclosure.

FIG. 2A illustrates a simplified cross-sectional schematic diagram of a processor package module in accordance with one or more embodiments of the disclosure. The processor package module 200A comprises a socket 204 having a first side and a second side, where the second side includes interconnect joints 206. A root complex 208 and a non-root complex are over the first side of the socket 204. The non-root complex 220A may or may not have wire leads. In the example embodiment shown in FIG. 2A, the non-root complex 220A has wire leads that are connected to a wire-to-board connector 212, and the wire-to-board connector 212 is over the first side of the socket 204. The second side of the socket 204 may be mounted to processor board 202, which includes board routing 216 connected to interconnect joints 206. The interconnect joints 206 can be solder bumps, gold bumps, conductive epoxy bumps, copper bumps, column-shaped bumps, spring-type connections, or any other suitable interconnect joint known in the art (e.g., a pin grid array, a land grid array, etc.), or any combination thereof.

According to the example embodiments, the root complex 208 and the non-root complex 220A are mounted to the socket through an interconnect layer 214 and a plurality of mixed-height socket pins, as described herein. The interconnect layer 214 is on the first side of the socket 204 and includes one or more levels of routing traces 222. In one embodiment, interconnect layer 214 is fabricated on the side of the socket to which IC devices, such as the root complex 208 and a wire-to-board connector 212 and/or a non-root complex 220A are mounted. This side may be referred to as the top side of the socket, while an opposite bottom side of the socket 204 is mounted to the processor board 202.

As used herein, socket 204 is a component used to provide a removable electrical and mechanical connection for an IC structure. In one embodiment, the socket 204 may comprise a land grid array (LGA) socket for example. The socket 204 may comprise a socket housing formed of any suitable material, such as LCP (liquid crystal polymer), Polyetherimide (PEI) thermoplastic material, polyamide, and the like. The socket housing may house other components and provide mechanical support. In embodiments, the processor board 202 may comprise a printed circuit board (PCB), an embedded multi-die interconnect bridge (EMIB), or an interposer, for example.

According to a first aspect of the example embodiment, the interconnect layer 214 connects the root complex 208 to the non-root complex 220A at the socket level. In the example shown, the non-root complex 220A includes wire leads to the wire-to-board connector 212. Additionally or alternatively, a non-root complex may directly mount to the interconnect layer 214 on the socket 204, as shown in FIGS. 2C and 2D.

As used herein, the term “root complex” refers to a package that contains a “root or host” die that serves as the primary or central processing unit (CPU) or main logic component. A “non-root complex” refers to a package that does not have a designated “root or host” die or a central processing unit controlling other components within the package. Typical non-root complexes may include GPUs, network interface cards, and storage controllers, for example.

According to a second aspect of the example embodiments, the processor package module 200A further comprises a first set of socket pins, referred to herein as high-speed socket pins 210A, that connect the root complex 208 and the wire-to-board connector 212 to the interconnect layer 214 on the socket 204. The root complex 208 is further connected to the wire-to-board connector 212 through the routing traces 222A in the interconnect layer 214, rather than having to go through the processor board. As shown, the high-speed socket pins 210A terminate within the interconnect layer 214 and convey high-speed signals between the root complex 208 and the wire-to-board connector 212. As used herein, high-speed signals may operate at frequencies beyond a few hundred gigahertz (GHz) and are used for high-speed data transfer and memory interfaces (e.g., next-generation Ethernet signals (200 Gbp/s-800 Gbp/s), and 224G ETH (224 gigabits per second (Gb/s)) and beyond).

A second set of socket pins, referred to as mid-speed socket pins 210B, extend through both the interconnect layer 214 and the socket 204 to interconnect joints 206 to connect the root complex 208 to the board routing 216 in the processor board 202. The mid-speed socket pins 210B convey mid-speed signals between the root complex 208 and the processor board 202. Mid-speed socket pins 210B are traditional socket pins that are modified in the sense that they are placed through both the interconnect layer 214 and the socket 204 the disclosed embodiments. As used herein, mid-speed signals may operate at frequencies of approximately a few hundred gigahertz (GHz) and are used for interconnecting various components within a system, such as memory, storage, and peripheral interfaces (e.g., 112G ETH (Ethernet) (112 Gb/s), and PCIe7 ((1×) 128 Gb/s).

A third set of socket pins, which may comprise traditional socket pins 210C, extend through the socket 204 to the interconnect joints 206 to connect the root complex 208 to the board routing 216 in the processor board 202. The low-speed socket pins 210B convey low-speed signals between the root complex 208 and the processor board 202, as done conventionally. As used herein, low-speed signals may operate at frequencies below a hundred gigahertz (GHz) and are used for communication between low-speed peripherals, sensors, and microcontrollers (e.g., GPIO (General-Purpose Input/Output) signals (133 MHz), DDR5/DDR6, and PCIe6 ((1×) 64 GB/s)).

FIG. 2B is a diagram illustrating a top view of the interconnect layer and the socket. The top surface of the socket 204 includes a plurality of socket contacts 218A. The top surface of the interconnect layer 214 includes a plurality of routing contacts 218B that are aligned over locations that socket contacts 218A would have occupied if not replaced by the routing contacts 218B. The high-speed socket contact pins 210A are in physical contact (soldered, mechanical, etc.) with the routing contacts 218B of the interconnect layer 214, while the mid-speed socket pins 210B extend through the socket contacts 218A, as shown in FIG. 2A. Placing the routing contacts 218B at original locations of the socket contacts 218A on the interconnect layer 214 has the advantage of providing the interconnect layer 214 with similar interconnect routing density as a standard package.

A first level of routing traces 222 (shown with solid lines) connects a first portion of the routing contacts 218B located beneath the root complex 208 to a second portion of the routing contacts 218B located beneath the wire-to-board connector 212. A second level of routing traces 222 (shown with dashed lines) lies beneath the first level routing traces that connect a third portion of the routing contacts 218B located beneath the root complex 208 with a fourth portion of the routing contacts 218B located beneath the wire-to-board connector 212. It should be appreciated that the introduction of interconnect layer 214 on the socket 204 may require an increase in the number of contacts required and hence increase socket form factor in an x- or y-direction (length or width), but not in the z-direction (height).

FIGS. 2C and 2D are nearly identical to FIG. 2A but illustrate embodiments for leveraging the use of the interconnect layer on the socket. In FIGS. 2C and 2D, processor package modules 200B and 200C are shown with non-root complexes 220B and 220C, respectively, directly mounted to the side of the interconnect layer 214 of the socket 204 through the high-speed socket pins 210A without the need for a wire-to-board connector. In one embodiment, the NCR package may comprise a GPU package (i.e., a packaged integrated circuit (IC) that contains a graphics processing unit) that does not receive other connections (i.e., a NCR (no connections received) package).

In another embodiment, the non-root package may comprise a photonic integrated circuit (PIC), or a combination of a PIC mounted to an EIC (electronic integrated circuits), as illustrated in FIG. 2D. The PIC is connected to an optical fiber, which may be useful for longer channel requirements and may be a solution requiring greater than 100 Gbp/s speed and greater than a 10-inch channel reach.

The disclosed processor package module architecture provides several advantages. Use of the interconnect layer 214 on the socket 204 enables selective height scaling of specific socket contact pins. That is, interconnect layer 214 enables the semiconductor package module to contain mixed-height socket pins, i.e., high-speed socket pins 210A, mid-speed socket pins 210B, and traditional socket pins 210C, for strategic enabling of high-speed complexes.

Another advantage is that the interconnect layer 214 interconnects two IC devices (e.g., root complex 208 and wire-to-board connector 212) mounted to the socket without having to route high-speed signals through the processor board 202, resulting in less impedance discontinuity leading to low-loss interconnect. The high-speed routing signals can be implemented at tighter pitch socket contacts by using the interconnect layer independent of the board breakout requirement.

A further advantage is that the high-speed socket pins 210A have a z-height that is significantly less than the z-height of socket pins 210C (and 210B) to enable much wider and faster bandwidth between the IC devices than the traditional socket pins 210C. This enables the processor package module to dispense with the need for board-level routing and results in fewer vertical transitions and shorter interconnect length to enable longer channel reach between a CPU and peripherals. The shorter electrical interconnect length through the high-speed socket pins 210A provides improved signal-to-noise ratio.

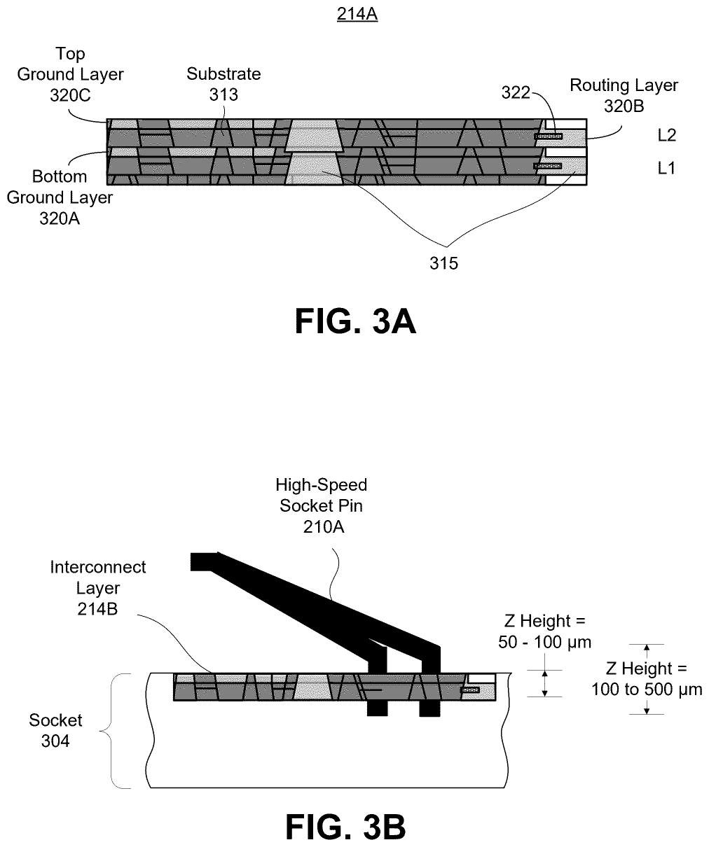

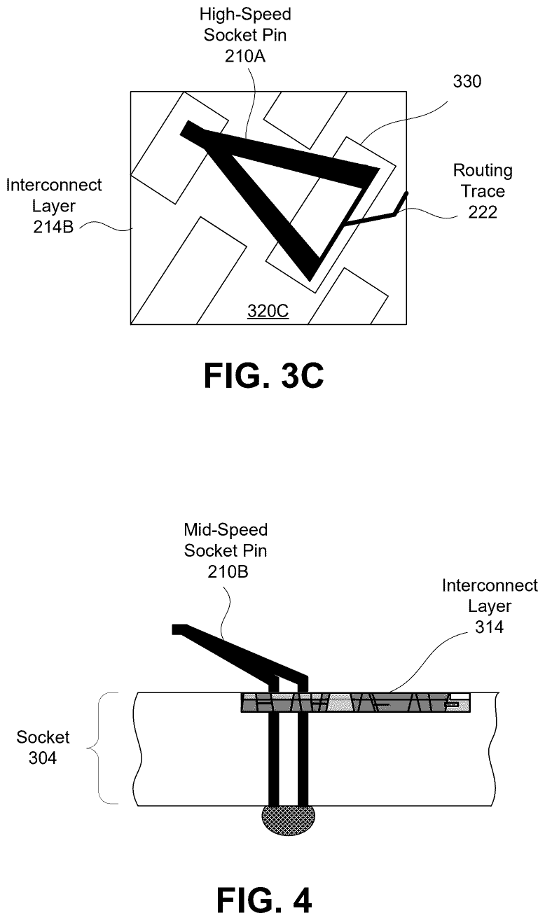

FIG. 3A illustrates an enlarged cross-sectional schematic diagram of a two-level interconnect layer in accordance with the disclosed embodiments. In one embodiment, the two-level interconnect layer 214A comprises two levels of routing traces 322, where a routing trace refers to a conductive line. In the example embodiments of FIGS. 2A and 3A, interconnect layers 214/214A are shown comprising two levels of routing traces 222/322.

According to the disclosed embodiments, each level of the interconnect layer 214A comprises three layers: a bottom ground layer 320A, a routing layer 320B containing the routing traces 322, and a top ground layer 320C. Thus, each level includes one routing layer 320B between two ground layers 320A and 320C. In embodiments, a ground layer is shared between adjacent levels. For example, the top ground layer for level 1 is the same as the bottom ground layer for level 2. In the interconnect layer 214A, the number of ground layers is always one more than the number of routing layers 320B. Introduction of interconnect layers 214/214A may require an increase in socket contact count and hence increased socket form factor lengthwise (x-direction) but not in z-height. As shown in FIG. 3B, in one embodiment, each level of the interconnect layer 214A may range from approximately 50-100 μm in z-height.

Standard package design rule may be used for modeling the interconnect layer 214/214A on the socket. To fabricate the interconnect layer, a recess may be formed in the socket housing at the intended location for the interconnect layer. In embodiments, the interconnect layer may comprise a substrate 313 comprising a composite material made of glass-reinforced epoxy resin (RF4), glass, silicon, or ceramic material. In the embodiment where the interconnect layer comprises glass, the glass substrate may comprise a solid glass core material with an amorphous crystal structure. The substrate 313 may also include various structures, such as vias, cavities, channels, or other features, that are filled with one or more other materials, such as dielectric materials 315, metal and metal alloys (e.g., routing traces 322), and the like.).

The materials forming the substrate may be CTE (coefficient of thermal expansion) matched with the materials forming the socket housing. For example, a glass substrate may be CTE matched with an LCP (liquid crystal polymer) socket housing to result in lower warpage risk. The interconnect layer may be manufactured using Laser Direct Structuring by allowing metal conductor fabrication on the dielectric layer. In one embodiment, the interconnect layer may further include alignment features that allow the interconnect layer to be aligned with alignment features of the socket, e.g. self-aligned using pin-holes on the socket and the interconnect layer.

FIG. 3B illustrates an angled cross-sectional schematic diagram of a high-speed socket pin coupled to, and terminates at, a single-level interconnect layer 214B rather than extending through a z-height of the socket.

High-speed socket pin 210A has a portion extending above the socket 304, and a second portion (referred to as a prong) that terminates within the interconnect layer 214B near the surface of the socket 304. In another embodiment, the second portion of the high-speed socket pin 210A terminates just past the bottom level of the interconnect layer 214B. In embodiments, the high-speed socket pin 210A may have a z-height ranging from approximately 100 to 500 μm for up to a 4-level interconnect layer 214B. The high-speed socket pins 210A can be considered traditional socket pins 210C that have been modified to have shorter second portions. Compared with the traditional socket pins 110/210C that extend through z-height of the socket 204, the high-speed socket pins 210A shown in FIG. 3B have a z-height that is significantly less than traditional socket pins 110/210C.

FIG. 3C illustrates a top view of the interconnect layer and the high-speed socket pin. As shown, the high-speed socket is in contact with one of the routing traces 222 in the interconnect layer 214B through a cutout 330 in the top ground layer 320C, which forms the top surface of interconnect layer 214B.

FIG. 4 illustrates an angled cross-sectional schematic diagram of a mid-speed socket pin extending through single-level interconnect layer 314 and through the z-height of socket 304. The mid-speed socket pins 210B can be considered traditional socket pins 210C whose only modification is the placement through the interconnect layer—there is no modification to the structure of traditional socket pins 210C itself. Although FIGS. 3B-3C and FIG. 4 illustrate the high-speed socket pin 210A and mid-speed socket pin 210B as having two prongs that form a triangle shape, high-speed socket pin 210A and mid-speed socket pin 210B may be formed with one prong or more than two prongs.

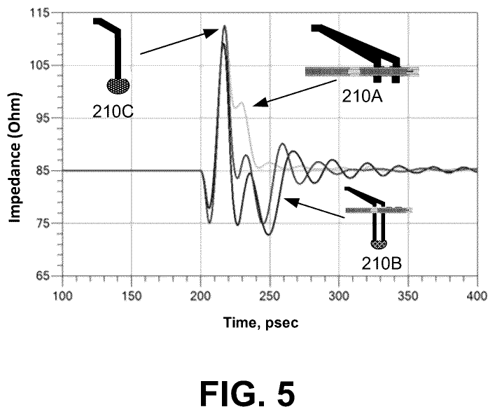

FIG. 5 illustrates a graph showing improvement in impedance when mixed-height socket pins of the disclosed embodiments are used. FIG. 5 illustrates impedance in Ohms over time. A graph for traditional socket pins 210C illustrates the baseline case versus graphs for the mid-speed socket pins 210B and high-speed socket pins 210A, which shows overall impedance.

In the impedance profile of FIG. 5, it is observed that discontinuity has been largely reduced. Additionally, if the absence of processor board breakout region impact is considered, the mid-speed socket pins 210B through the interconnect layer will have much superior performance over traditional socket pins 210C. The result shows that by modifying existing traditional socket pins 210C to extend through the interconnect layer, performance at the base level improves without any modification of the socket pin itself.

It is worth noting, that the implementation of an interconnect layer in the socket will consider a balance between performance and cost. The material and process needed for design rules and performances can be expensive. As of today, a majority of the current suppliers do not have the capability to handle it. A continuous innovation in low-loss material is required to keep up with the ever-growing data rate demand. The material improvement can hit a fundamental limit at a very high frequency. The traditional electrical channel reach may not keep up with the increasing data rate without costly material. However, the disclosed implementation of the interconnect layer, the mid-speed socket pins 210B, and the high-speed socket pins 210A can be an alternate low-cost solution providing shorter channel reach possibility.

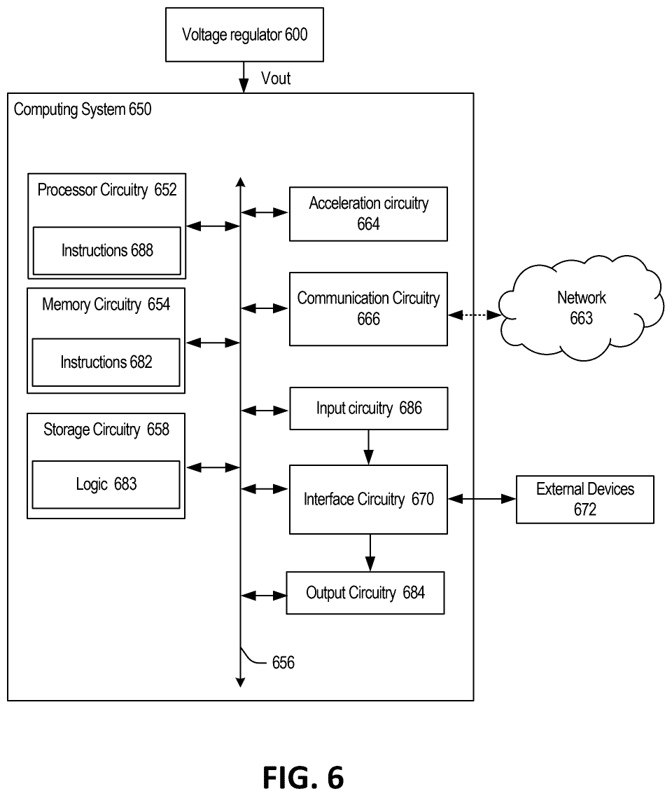

FIG. 6 illustrates an example of components that may be present in a computing system 650 for implementing the techniques (e.g., operations, processes, methods, and methodologies) described herein. The CFET memory cell described herein can be used in any of the components of the computing system 650. One example implementation involves the memory circuitry 654.

The voltage regulator 600 may provide a voltage Vout to one or more of the components of the computing system 650.

The memory circuitry 654 may store instructions and the processor circuitry 652 may execute the instructions to perform the functions described herein.

The computing system 650 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 650, or as components otherwise incorporated within a chassis of a larger system. For one embodiment, at least one processor 652 may be packaged together with computational logic 682 and configured to practice aspects of various example embodiments described herein to form a System in Package (SiP) or a System on Chip (SoC).

The system 650 includes processor circuitry in the form of one or more processors 652. The processor circuitry 652 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 652 may include one or more hardware accelerators (e.g., same or similar to acceleration circuitry 664), which may be microprocessors, programmable processing devices (e.g., FPGA, ASIC, etc.), or the like. The one or more accelerators may include, for example, computer vision and/or deep learning accelerators. In some implementations, the processor circuitry 652 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 652 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 652 may be coupled with or may include memory/storage and may be configured to execute instructions stored in the memory/storage to enable various applications or operating systems to run on the platform 650. The processors (or cores) 652 is configured to operate application software to provide a specific service to a user of the platform 650. In some embodiments, the processor(s) 652 may be a special-purpose processor(s)/controller(s) configured (or configurable) to operate according to the various embodiments herein.

As examples, the processor(s) 652 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 652 may be a part of a system on a chip (SoC), System-in-Package (SiP), a multi-chip package (MCP), and/or the like, in which the processor(s) 652 and other components are formed into a single integrated circuit, or a single package. Other examples of the processor(s) 652 are mentioned elsewhere in the present disclosure.

The system 650 may include or be coupled to acceleration circuitry 664, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 664 may comprise logic blocks or logic fabric and other interconnected resources that may be programmed (configured) to perform various functions, such as the procedures, methods, functions, etc. of the various embodiments discussed herein. In such implementations, the acceleration circuitry 664 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 652 and/or acceleration circuitry 664 may include hardware elements specifically tailored for machine learning and/or artificial intelligence (AI) functionality. In these implementations, the processor circuitry 652 and/or acceleration circuitry 664 may be, or may include, an AI engine chip that can run many different kinds of AI instruction sets once loaded with the appropriate weightings and training code. Additionally or alternatively, the processor circuitry 652 and/or acceleration circuitry 664 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 652 and/or acceleration circuitry 664 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 670 provided by Huawei®, and/or the like. In some hardware-based implementations, individual subsystems of system 650 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 650 also includes system memory 654. Any number of memory devices may be used to provide for a given amount of system memory. As examples, the memory 654 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 654 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 654 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 658 provides persistent storage of information such as data, applications, operating systems and so forth. In an example, the storage 658 may be implemented via a solid-state disk drive (SSDD) and/or high-speed electrically erasable memory (commonly referred to as “flash memory”). Other devices that may be used for the storage 658 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 654 and/or storage circuitry 658 may also incorporate three-dimensional (3D) cross-point (XPOINT) memories from Intel® and Micron®.

The memory circuitry 654 and/or storage circuitry 658 is/are configured to store computational logic 683 in the form of software, firmware, microcode, or hardware-level instructions to implement the techniques described herein. The computational logic 683 may be employed to store working copies and/or permanent copies of programming instructions, or data to create the programming instructions, for the operation of various components of system 650 (e.g., drivers, libraries, application programming interfaces (APIs), etc.), an operating system of system 650, one or more applications, and/or for carrying out the embodiments discussed herein. The computational logic 683 may be stored or loaded into memory circuitry 654 as instructions 682, or data to create the instructions 682, which are then accessed for execution by the processor circuitry 652 to carry out the functions described herein. The processor circuitry 652 and/or the acceleration circuitry 664 accesses the memory circuitry 654 and/or the storage circuitry 658 over the interconnect (IX) 656. The instructions 682 direct the processor circuitry 652 to perform a specific sequence or flow of actions, for example, as described with respect to flowchart(s) and block diagram(s) of operations and functionality depicted previously. The various elements may be implemented by assembler instructions supported by processor circuitry 652 or high-level languages that may be compiled into instructions 688, or data to create the instructions 688, to be executed by the processor circuitry 652. The permanent copy of the programming instructions may be placed into persistent storage devices of storage circuitry 658 in the factory or in the field through, for example, a distribution medium (not shown), through a communication interface (e.g., from a distribution server (not shown)), over-the-air (OTA), or any combination thereof.

The IX 656 couples the processor 652 to communication circuitry 666 for communications with other devices, such as a remote server (not shown) and the like. The communication circuitry 666 is a hardware element, or collection of hardware elements, used to communicate over one or more networks 663 and/or with other devices. In one example, communication circuitry 666 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 666 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 656 also couples the processor 652 to interface circuitry 670 that is used to connect system 650 with one or more external devices 672. The external devices 672 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 650, which are referred to as input circuitry 686 and output circuitry 684. The input circuitry 686 and output circuitry 684 include one or more user interfaces designed to enable user interaction with the platform 650 and/or peripheral component interfaces designed to enable peripheral component interaction with the platform 650. Input circuitry 686 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 684 may be included to show information or otherwise convey information, such as sensor readings, actuator position(s), or other like information. Data and/or graphics may be displayed on one or more user interface components of the output circuitry 684. Output circuitry 684 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 650. The output circuitry 684 may also include speakers and/or other audio emitting devices, printer(s), and/or the like. Additionally or alternatively, sensor(s) may be used as the input circuitry 686 (e.g., an image capture device, motion capture device, or the like) and one or more actuators may be used as the output device circuitry 684 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 650 may communicate over the IX 656. The IX 656 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 656 may be a proprietary bus, for example, used in a SoC based system.

The number, capability, and/or capacity of the elements of system 650 may vary, depending on whether computing system 650 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 650 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1. A processor package module, comprising: a socket having a first side and a second side, where the second side includes interconnect joints. The socket further includes a root complex and a non-root complex over the first side; an interconnect layer is on the first side of the socket, the interconnect layer having one or more levels of routing traces; and a first set of socket pins connecting the root complex and non-root package to the interconnect layer on the socket, the first set of socket pins terminating at the interconnect layer.

Example embodiment 2. The processor package module of Example embodiment 1, wherein a first plurality of the routing traces of the interconnect layer connects the root complex to the non-root complex.

Example embodiment 3. The processor package module of Example embodiment 1 or 2, wherein the first set of socket pins convey high-speed signals between the root complex and the non-root complex.

Example embodiment 4. The processor package module of Example embodiment 3, wherein high-speed signals operate at frequencies beyond a few hundred gigahertz (GHz).

Example embodiment 5. The processor package module of Example embodiment 1, 2, 3, or 4, further comprising: a processor board having board routing, the socket mounted on the processor board with the interconnect joints; and a second set of socket pins that extend through both the interconnect layer and the socket to the interconnect joints to connect the root complex to the board routing in the processor board.

Example embodiment 6. The processor package module of Example embodiment 5, wherein the second set of socket pins convey mid-speed signals between the root complex and the board routing in the processor board.

Example embodiment 7. The processor package module of Example embodiment 6, wherein mid-speed signals operate at frequencies of approximately a few hundred gigahertz (GHz).

Example embodiment 8. The processor package module of Example embodiment 5, 6, or 7, further comprising: a third set of socket pins that extend through the socket to the interconnect joints to connect the root complex to the board routing in the processor board.

Example embodiment 9. The processor package module of Example embodiment 8, wherein the third set of socket pins convey low-speed signals between the root complex and the board routing in the processor board.

Example embodiment 10. The processor package module of Example embodiment 9, wherein low-speed signals operate at frequencies below a hundred gigahertz (GHz).

Example embodiment 11. A processor package module, comprising: a processor board; and a socket having a first side and a second side, the second side includes interconnect joints connected to the processor board. The socket further includes a first semiconductor package and a second semiconductor package over the first side. An interconnect layer is on the first side of the socket, the interconnect layer having one or more levels of routing traces; a first set of socket pins connecting the first semiconductor package and second semiconductor package to the routing traces in the interconnect layer, the first set of socket pins terminating at the interconnect layer; and a second set of socket pins that extend through both the interconnect layer and the socket to connect the first semiconductor package to the processor board.

Example embodiment 12. The processor package module of Example embodiment 11, wherein the socket has a z-height ranging from approximately 1.5 to 2.5 mm.

Example embodiment 13. The processor package module of Example embodiment 11 or 12, further comprising: a third set of socket pins connecting the first semiconductor package to the processor board, wherein the second set of socket pins and the third set of socket pins have a first z-height, and wherein the first set of socket pins has a second z-height that is less than the first z-height.

Example embodiment 14. The processor package module of Example embodiment 13, wherein the first z-height of the first set of socket pins ranges from approximately 100 to 500 μm.

Example embodiment 15. The processor package module of Example embodiment 13, wherein the first set of socket pins convey a first signal at a first frequency, wherein the second set of socket pins convey a second signal at a second frequency, and the third set of socket pins convey a third signal at a third frequency.

Example embodiment 16. The processor package module of Example embodiment 15, wherein the first frequency is higher than the second frequency, and the second frequency is higher than the third frequency.

Example embodiment 17. A processor package module, comprising: a processor board; a socket having a first side and a second side, the second side mounted to the processor board. The socket further includes a root complex and a non-root complex over the first side. An interconnect layer is on the first side of the socket, the interconnect layer comprising one or more levels of routing traces. A plurality of mixed-height socket pins connects the root complex to the socket, the plurality of mixed-height socket pins comprising: a first set of socket pins that terminate at the interconnect layer and connect the root complex to the non-root complex through the one or more levels of routing traces in the interconnect layer. A second set of socket pins extends through both the interconnect layer and the socket to connect the root complex to the processor board. A third set of socket pins extend through the socket, but not the interconnect layer, to connect the root complex to the processor board.

Example embodiment 18. The processor package module of Example embodiment 17, wherein the one or more levels each comprise: a bottom ground layer, a routing layer containing the routing traces, and a top ground layer.

Example embodiment 19. The processor package module of Example embodiment 17 or 18, wherein the first side of the socket comprises socket contacts, and a top surface of the interconnect layer comprises a plurality of routing contacts, and wherein the first set of socket pins are in physical contact with the plurality of routing contacts of the interconnect layer.

Example embodiment 20. The processor package module of Example embodiment 17, 18, or 19, wherein the first set of socket pins convey high-speed signals operating at frequencies ranging from several gigahertz to tens of gigahertz.

What is claimed is:

1. A processor package module, comprising:
a socket having a first side and a second side, where the second side includes interconnect joints;
a root complex over the first side;
a non-root complex over the first side;
an interconnect layer is on the first side of the socket, the interconnect layer having one or more levels of routing traces; and
a first set of socket pins connecting the root complex and non-root package to the interconnect layer on the socket, the first set of socket pins terminating at the interconnect layer.

2. The processor package module of claim 1, wherein a first plurality of the routing traces of the interconnect layer connects the root complex to the non-root complex.

3. The processor package module of claim 1, wherein the first set of socket pins convey high-speed signals between the root complex and the non-root complex.

4. The processor package module of claim 3, wherein high-speed signals operate at frequencies beyond a few hundred gigahertz (GHz).

5. The processor package module of claim 1, further comprising:
a processor board having board routing, the socket mounted on the processor board with the interconnect joints; and
a second set of socket pins that extend through both the interconnect layer and the socket to the interconnect joints to connect the root complex to the board routing in the processor board.

6. The processor package module of claim 5, wherein the second set of socket pins convey mid-speed signals between the root complex and the board routing in the processor board.

7. The processor package module of claim 6, wherein mid-speed signals operate at frequencies of approximately a few hundred gigahertz (GHz).

8. The processor package module of claim 5, further comprising:
a third set of socket pins that extend through the socket to the interconnect joints to connect the root complex to the board routing in the processor board.

9. The processor package module of claim 8, wherein the third set of socket pins convey low-speed signals between the root complex and the board routing in the processor board.

10. The processor package module of claim 9, wherein low-speed signals operate at frequencies below a hundred gigahertz (GHz).

11. A processor package module, comprising:
a processor board;
a socket having a first side and a second side, where the second side includes interconnect joints connected to the processor board;
a first semiconductor package over the first side;
a second semiconductor package over the first side;
an interconnect layer on the first side of the socket, the interconnect layer having one or more levels of routing traces;
a first set of socket pins connecting the first semiconductor package and second semiconductor package to the routing traces in the interconnect layer, the first set of socket pins terminating at the interconnect layer; and
a second set of socket pins that extend through both the interconnect layer and the socket to connect the first semiconductor package to the processor board.

12. The processor package module of claim 11, wherein the socket has a z-height ranging from approximately 1.5 to 2.5 mm.

13. The processor package module of claim 11, further comprising:
a third set of socket pins connecting the first semiconductor package to the processor board, wherein the second set of socket pins and the third set of socket pins have a first z-height,
wherein the first set of socket pins has a second z-height that is less than the first z-height.

14. The processor package module of claim 13, wherein the first z-height of the first set of socket pins ranges from approximately 100 to 500 μm.

15. The processor package module of claim 13, wherein the first set of socket pins convey a first signal at a first frequency, wherein the second set of socket pins convey a second signal at a second frequency, and the third set of socket pins convey a third signal at a third frequency.

16. The processor package module of claim 15, wherein the first frequency is higher than the second frequency, and the second frequency is higher than the third frequency.

17. A processor package module, comprising:
a processor board;
a socket having a first side and a second side, the second side mounted to the processor board;
a root complex over the first side;
a non-root complex over the first side;
an interconnect layer on the first side of the socket, the interconnect layer comprising one or more levels of routing traces; and
a plurality of mixed-height socket pins connecting the root complex to the socket, the plurality of mixed-height socket pins comprising:
a first set of socket pins that terminate at the interconnect layer and connect the root complex to the non-root complex through the one or more levels of routing traces in the interconnect layer;
a second set of socket pins that extend through both the interconnect layer and the socket to connect the root complex to the processor board; and
a third set of socket pins that extend through the socket, but not the interconnect layer, to connect the root complex to the processor board.

18. The processor package module of claim 17, wherein the one or more levels each comprise:
a bottom ground layer, a routing layer containing the routing traces, and a top ground layer.

19. The processor package module of claim 17, wherein the first side of the socket comprises socket contacts, and a top surface of the interconnect layer comprises a plurality of routing contacts, and wherein the first set of socket pins are in physical contact with the plurality of routing contacts of the interconnect layer.

20. The processor package module of claim 17, wherein the first set of socket pins convey high-speed signals operating at frequencies ranging from several gigahertz to tens of gigahertz.
